(19) United States
(12) Patent Application Publication
(10) Pub. No.: US 2007/0076468 A1
(43) Pub. Date: Apr. 5, 2007

(54) Asymmetric six transistor SRAM random access memory cell

(75) Inventor: Jean-Pierre Schoellkopf, Grenoble (FR)

Correspondence Address: JENKENS & GILCHRIST, PC, 1445 ROSS AVENUE, SUITE 3200, DALLAS, TX, 75202, US

(73) Assignee: STMicroelectronics S.A., Montrouge (FR)

(21) Appl. No.: 11/541,961

(22) Filed: Oct. 2, 2006

(30) Foreign Application Priority Data
Oct. 3, 2005 (FR) 0510090

(51) Int. Cl. G11C 11/00

(52) U.S. Cl. 365/154

(57) ABSTRACT

A random access memory cell includes a pair of complementary bit lines, a bistable circuit including first and second complementary read/write terminals, and two storage nodes. The first storage node is provided by a first nMos transistor and a first pMos transistor, and the second storage node is provided by a second nMos transistor and a second pMos transistor. A first switch transistor is connected between the first terminal and one of the lines of the bit line pair, and a second switch transistor is connected between the second terminal and the other line (BL) of the bit line pair. The two nMos transistors of the bistable circuit have different threshold voltages.

### PRIORITY CLAIM

This application claims priority from French Application for Patent No. 05 10090 filed Oct. 3, 2005, the disclosure of which is hereby incorporated by reference.

### BACKGROUND OF THE INVENTION

1. Technical Field of the Invention

The present invention relates in general to random access memories, in particular the SRAM-type (static random access memory) random access memory cell structure with a high read rate.

2. Description of Related Art

Such an SRAM random access memory cell is well known to a person skilled in the art, in particular from the example provided in U.S. Pat. No. 6,519,176 (the disclosure of which is hereby incorporated by reference), which describes the use of a symmetrical bistable circuit in an SRAM memory cell. To obtain a significant read current and, consequently, an improvement in the access time to the bit line at 1, the switch transistors have different threshold voltages. In this way, the threshold voltage of the switch transistor connecting the terminal of the bistable circuit to the bit line at 1 is lower than that of the other switch connecting the other terminal of the bistable circuit to the bit line at 0.

Market developments and technical advances make it necessary to produce materials that are always faster and more powerful. There is a need in the art to further improve the access time to the bit line at 1.

### SUMMARY OF THE INVENTION

To address the foregoing need, the cell of an embodiment of the invention, which is otherwise consistent with the general definition provided above, includes first and second nMos transistors of the bistable circuit having first and second threshold voltages of which the first is greater than the second, creating an asymmetry in the bistable circuit.

With this arrangement, the bit line at 1 is discharged through two series-mounted low-threshold voltage transistors, which increases the read/write access speed to the memory cell.

Another advantage of this arrangement lies in the fact that the initial state is ensured. The advantage of this is a known state of the contents of the memory after the current is turned on, avoiding a resetting sequence, for example, before starting an application.

This asymmetric memory cell configuration increases the access speed to the cell but simultaneously increases the leakage current. The increase in the leakage current contributes to the increase in the total static consumption of the circuit, but only when the memory point of the read/write terminal contains the value opposite that of its initial state. The invention therefore finds a compromise between the increase in the read/write speed and the increase in the static consumption.

In the preferred embodiment of the invention, the first and second switch transistors have first and second respective threshold voltages of which the first is greater than the second; more specifically, the second switch transistor and the second nMos transistor have the same threshold voltage.

A number of methods are known for obtaining differences in threshold voltages between transistors. Preferably, the differences in threshold voltage of the transistors result from different ion implantations by different masking levels.

Current technical constraints in production require two adjacent transistors to have the same threshold voltage.

Thus, topographically, the first switch transistor and the first nMos transistor of the bistable circuit are series-mounted on a first side of the random access memory cell, and the second switch transistor and the second nMos transistor of the bistable circuit are series-mounted on a second side, opposite the first side, of the random access memory cell.

Preferably, the second switch transistor and the second nMos transistor of the bistable circuit, which are mounted in series on the second side of the random access memory cell, are adjacent.

Similarly, the first switch transistor and the first nMos transistor of the bistable circuit, series-mounted on the first side of the random access memory cell are preferably adjacent.

In addition, the gates of the switch transistors are advantageously connected to a same word selection line.

Finally, according to another feature of the invention, a plurality of random access memory cells thus described can be assembled in matrix form.

In a particular embodiment, a six-transistor random access memory cell includes: a pair of complementary bit lines; a bistable circuit including first and second complementary read/write terminals; and including first and second respective storage nodes, the first storage node consisting of a first nMos transistor and a first pMos transistor; the second storage node consisting of a second nMos transistor and a second pMos transistor; a first switch transistor connected between the first terminal and one of the lines of the bit line pair; and a second switch transistor connected between the second terminal and the other line of the bit line pair.

In accordance with an embodiment, a rectangular cell design for a six transistor SRAM memory cell comprises: a first P WELL for first nMos transistors of the cell, wherein at least one of the first nMos transistors has a first threshold voltage which is relatively high; an N WELL adjacent the P WELL for pMos transistors of the cell; and a second P WELL adjacent the N WELL and on an opposite side of the N WELL from the first P WELL for second nMos transistors of the cell, wherein at least one of the second nMos transistors has a second threshold voltage which is relatively low.

### BRIEF DESCRIPTION OF THE DRAWINGS

A more complete understanding of the method and apparatus of the present invention may be acquired by reference to the following Detailed Description when taken in conjunction with the accompanying Drawings wherein:

FIG. 1 is a representation of a memory cell according to the invention; and

FIG. 2 is a top view of a memory cell according to the invention in 45-nm technology, provided for the purpose of indication, but the invention is not limited to this technological generation.

### DETAILED DESCRIPTION OF THE DRAWINGS

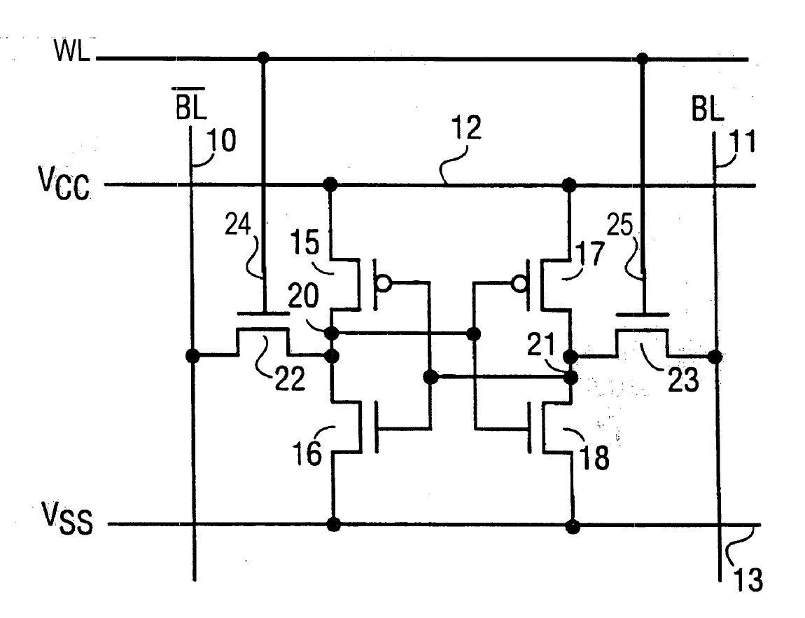

FIG. 1 shows a random access memory cell including a pair of complementary bit lines BL and /BL, and a bistable circuit.

The bistable circuit includes two complementary read/write terminals 20, 21, and two storage nodes 15 to 18.

The first storage node comprises a first nMos transistor 16 and a first pMos transistor 15 of which the gates are connected to one another and to the second read/write terminal 21. The second storage node comprises a second nMos transistor 18 and a second pMos transistor 17 of which the gates are connected to one another and to the first read/write terminal 20.

A first switch transistor 22 is connected between the first terminal 20 and one of the lines /BL of the bit line pair. A second switch transistor 23 is connected between the second terminal 21 and the other line BL of the bit line pair.

Power is supplied to the bistable circuit by means of lines 12 and 13, typically with line 12 having a positive potential and line 13 being at the ground.

The two pMos transistors of the bistable circuit are arranged so that their drain is connected to the power source line 12.

According to one feature, the first 16 and second 18 nMos transistors of the bistable circuit have respective first and second threshold voltages of which the first is greater than the second.

According to another feature, the first 22 and second 23 switch transistors have respective first and second threshold voltages of which the first is greater than the second.

The second switch transistor 23 and the second nMos transistor 18 preferably have the same threshold voltage and in particular a rather low threshold voltage.

The first switch transistor 22 and the first nMos transistor 16 preferably have the same threshold voltage and in particular a rather high threshold voltage.

The variations in the threshold voltages of transistors with a high threshold voltage (HVT) and the transistors with a low threshold voltage (LVT) are such that min (HVT)>max (LVT); for example HVT=0.6 V+/−10% (min=0.54 V) and LVT=0.4 V+/−10% (max=0.44 V).

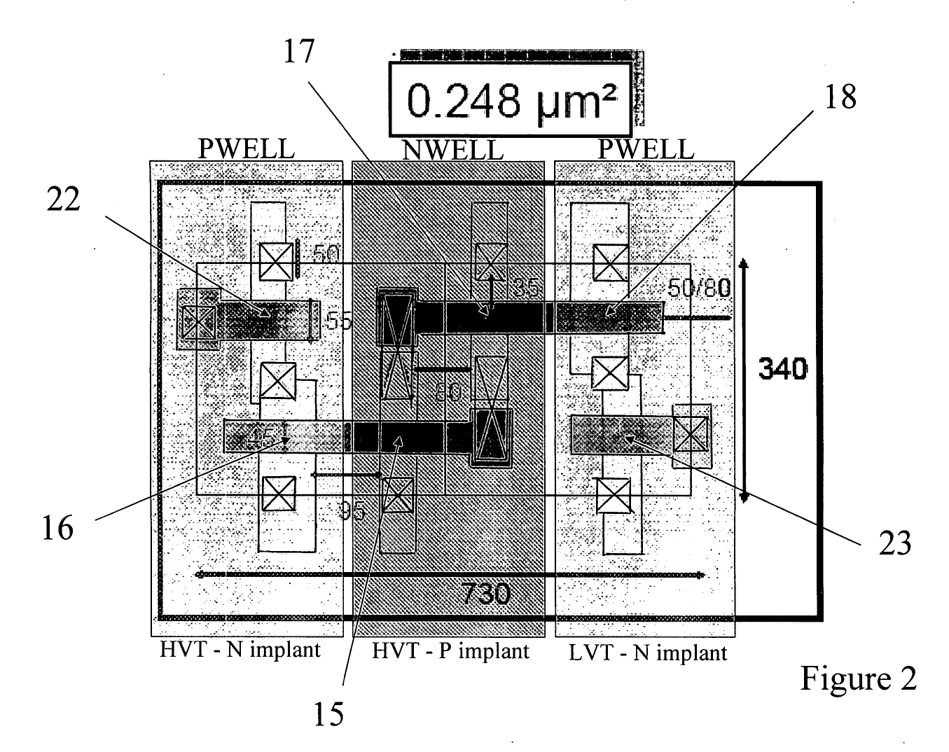

As shown in FIG. 2, the first switch transistor 22 and the first nMos transistor 16 of the bistable circuit are advantageously series-mounted on a first side of the random access memory cell, and the second switch transistor 23 and the second nMos transistor 18 of the bistable circuit are series-mounted on a second side, opposite the first side, of the random access memory cell.

The second switch transistor 23 and the second nMos transistor 18 of the bistable circuit, series-mounted on the second side of the random access memory cell are preferably adjacent.

Similarly, the first switch transistor 22 and the first nMos transistor 16 of the bistable circuit, series-mounted on the first side of the random access memory cell are preferably adjacent.

The gate 24 of switch transistor 22 is connected to the gate 25 of switch transistor 23, preferably by means of the same word selection line WL. The same word selection line thus controls the reading/writing to the bit lines of the cell thus selected.

The differences in threshold voltage of the transistors result from different ion implantations.

The asymmetry of the threshold voltages by ion implantations is made possible, for a rectangular cell design, by the existence of an alternation:
of a well P (PWELL) at the left with nMos transistors having a high threshold voltage (HVT),
of a well N (NWELL) in the middle with pMos transistors having a high threshold voltage (HVT),
of a well P (PWELL) at the right with nMos transistors having a low threshold voltage (LVT).

This asymmetry is valid for all technologies, even the smallest, namely, for example in 45-nm technology, rectangular cell dimensions of 0.73 μm by 0.34 μm as shown in FIG. 2.

A plurality of random access memory cells as described above can be assembled so as to form a matrix.

When activated, the memory cell takes an initial value. Without asymmetry, the initial value is random, with the same probability of having 0 or 1 at the read/write terminals. In the presence of an asymmetry, in this case a difference in threshold voltage between the two nMos transistors of two storage nodes of the bistable circuit, the initial value is ensured. Indeed, the potential of the two storage nodes follows the increase in the power supply, until the nMos transistor that has the lowest threshold voltage becomes a conductor; there is then an irreversible switchover on one side: the value “0” on the drain of the transistor having a low threshold voltage.

Although preferred embodiments of the method and apparatus of the present invention have been illustrated in the accompanying Drawings and described in the foregoing Detailed Description, it will be understood that the invention is not limited to the embodiments disclosed, but is capable of numerous rearrangements, modifications and substitutions without departing from the spirit of the invention as set forth and defined by the following claims.

What is claimed is:

1. A random access memory cell, comprising:
a pair of complementary bit lines;
a bistable circuit including first and second complementary read/write terminals, and including first and second respective storage nodes, the first storage node provided by a first nMos transistor and a first pMos transistor and the second storage node provided by a second nMos transistor and a second pMos transistor;
a first switch transistor connected between the first read/write terminal and one of the lines of the bit line pair;
a second switch transistor connected between the second read/write terminal and the other line of the bit line pair,
wherein the first and second nMos transistors of the bistable circuit have respective first and second threshold voltages of which the first is greater than the second, and the first and second switch transistors have respective first and second threshold voltages of which the first is greater than the second.

2. The random access memory cell according to claim 1, wherein the second switch transistor and the second nMos transistor have the same threshold voltage.

3. The random access memory cell according to claim 1, wherein the first switch transistor and the first nMos transistor have the same threshold voltage.

4. The random access memory cell according to claim 1, wherein the first switch transistor and the first nMos transistor of the bistable circuit are series-mounted on a first side of the random access memory cell, and wherein the second switch transistor and the second nMos transistor of the bistable circuit are series-mounted on a second side, opposite the first side, of the random access memory cell.

5. The random access memory cell according to claim 4, wherein the second switch transistor and the second nMos transistor of the bistable circuit, series-mounted on the second side of the random access memory cell, are adjacent.

6. The random access memory cell according to claim 4, wherein the first switch transistor and the first nMos transistor of the bistable circuit, series-mounted on the first side of the random access memory cell, are adjacent.

7. The random access memory cell according to claim 1, wherein the differences in threshold voltage of the transistors result from different ion implantations.

8. The random access memory cell according to claim 1, wherein gates of the switch transistors are connected to the same word selection line.

9. A matrix of memory cells comprising a plurality of random access memory cells wherein each memory cell comprises:
a pair of complementary bit lines;
a bistable circuit including first and second complementary read/write terminals, and including first and second respective storage nodes, the first storage node provided by a first nMos transistor and a first pMos transistor and the second storage node provided by a second nMos transistor and a second pMos transistor;
a first switch transistor connected between the first read/write terminal and one of the lines of the bit line pair;
a second switch transistor connected between the second read/write terminal and the other line of the bit line pair,
wherein the first and second nMos transistors of the bistable circuit have respective first and second threshold voltages of which the first is greater than the second, and the first and second switch transistors have respective first and second threshold voltages of which the first is greater than the secondaccording to any one of the previous claims.

10. A bistable circuit for a six transistor SRAM memory cell, the bistable circuit comprising:
a first p-channel transistor coupled in series with a first n-channel transistor at a first node;
a second p-channel transistor coupled in series with a second n-channel transistor at a second node;
a first connection between the first node and gate terminals of the second p-channel transistor and second n-channel transistor;
a second connection between the second node and gate terminals of the first p-channel transistor and first n-channel transistor;
wherein the first and second nMos transistors of the bistable circuit have respective first and second threshold voltages of which the first is greater than the second.

11. A rectangular cell design for a six transistor SRAM memory cell, comprising:
a first P WELL for first nMos transistors of the cell, wherein at least one of the first nMos transistors has a first threshold voltage which is relatively high;
an N WELL adjacent the P WELL for pMos transistors of the cell; and
a second P WELL adjacent the N WELL and on an opposite side of the N WELL from the first P WELL for second nMos transistors of the cell, wherein at least one of the second nMos transistors has a second threshold voltage which is relatively low.

12. The design of claim 11 wherein at least one of the pMos transistors has the first threshold voltage which is relatively high.

13. The design of claim 11 wherein the at least one of the first nMos transistors is a first nMos pull down transistor of a bistable circuit of the six transistor SRAM memory cell and wherein the at least one of the second nMos transistors is a second nMos pull down transistor of the bistable circuit of the six transistor SRAM memory cell.

14. The design of claim 11 wherein the at least one of the first nMos transistors is a first nMos bit line access transistor of the six transistor SRAM memory cell and wherein the at least one of the second nMos transistors is a second nMos bit line access transistor of the six transistor SRAM memory cell.

15. The design of claim 11 wherein a minimal value of the relatively high first threshold voltage exceeds a maximal value of the relatively low second threshold voltage.

16. The design of claim 11 wherein the relatively high first threshold voltage is about 0.6 Volts and the relatively low second threshold voltage is about 0.4 Volts.
